(19) United States
(12) Patent Application Publication
(10) Pub. No.: US 2011/0121326 A1
(43) Pub. Date: May 26, 2011

(54) Submount Having Reflective Cu-Ni-Ag Pads Formed Using Electroless Deposition

(75) Inventors: Kia Kuang Tan, Penang (MY); Wah Sheng Teoh, Penang (MY)

(73) Assignee: DSEM HOLDINGS SDN. BHD., Penang (MY)

(21) Appl. No.: 12/953,358

(22) Filed: Nov. 23, 2010

(30) Foreign Application Priority Data
Nov. 26, 2009 (MY) PI 20095059

(51) Int. Cl. H01L 33/62; H05K 3/10; H01L 33/46

(52) U.S. Cl. 257/88; 29/846; 257/98; 257/E33.066; 257/E33.068

(57) ABSTRACT

A submount for an LED has relatively large copper pads formed on its top surface using an electroless process so that no electrical bias circuitry is required for the submount. The copper pads are then coated with nickel using an electroless process. The nickel layer is then coated with silver using an electroless process, such as an immersion silver process. In one embodiment, the silver layer is less than one micron thick. The Ni layer prevents a reduction in reflectivity of the Ag after long periods of use while conducting the high current (300 mA to >1 amp) needed for high power LEDs. The silver layer surrounds at least 75% of the periphery of the LED die and extends at least 1 mm around the periphery of the die to reflect the LED light.

### FIELD OF THE INVENTION

This invention relates to forming metal pads on submounts for contacting electrodes of solid state lighting devices, such as light emitting diodes (LEDs), and, in particular, to a technique for forming highly reflective pads that maintain high reflectivity throughout the long life of the lighting device.

### BACKGROUND

High-power light emitting diodes mounted on a submount may draw current in excess of an ampere. Therefore, it is desirable to provide very low resistivity metal traces on the submount. Copper is an excellent conductor but is not good for soldering or for ultrasonic welding. It is known to plate a thin layer of gold over a copper bonding pad with a nickel barrier layer in-between. The nickel layer is needed to prevent the copper atoms from diffusing through the gold layer, causing tarnishing of its surface and formation of an oxide/sulfide layer.

Although gold is a good corrosion-resistant and highly solderable finish for a metal pad on a circuit board, gold is not a good reflector for light having a wavelength less than about 600 nm (e.g., yellow to blue visible light).

Silver is solderable and a very good reflector for all visible light. It is known to plate silver directly over a copper pad for a solderable and reflective finish (to reflect LED light), such as described in U.S. Pat. No. 7,053,421. The U.S. Pat. No. 7,053,421 emphasizes that a benefit of plating silver directly over copper, versus a Cu—Ni—Au layer, is that there is no need for a nickel barrier layer. In the '421 patent, the Cu—Ag pads do not surround the LED die, so there is no emphasis on improving the efficiency of the LED die by reflecting light emitted by all four sides of the LED die. The '421 patent does not mention how the copper and silver layers were formed, so it is assumed a conventional electroplating technique was used to deposit the silver. It is also assumed that the silver layer has a typical plating thickness of over 3 microns.

The present inventors have performed extensive testing of copper traces plated with silver, where the copper plating was performed using an immersion silver process, which is an electroless process. Using an electroless process allows the metal deposition to occur without electrically biasing the copper. For electrically biasing the copper on a wafer scale (prior to small circuit boards being singulated from a large sheet of circuit boards), sacrificial connectors must be created connecting every trace to the biasing source. Such sacrificial traces are then cut after the plating process. Cutting such sacrificial traces exposes the edges of the copper, subjecting the copper to corrosion and increasing the likelihood of delamination of the silver. The sacrificial traces also add expense and complexity. This is avoided with electroless deposition.

The lifetime of an LED is greater than 50,000 hours, and some manufacturers indicate the lifetime may be up to 100,000 hours (about 11 years). The present inventors tested Cu—Ag pads after a stress test involving wet and hot conditions over 1000 hours while the pads were conducting a relatively high current (around 1 amp) driving a high power LED. This simulated conditions well over a typical 1000 hours of use of a high power LED bonded to the silver plated pads. The silver was deposited using an immersion silver process, where the plating process (a chemical reaction) automatically stops the moment the initial metal surface has been coated with silver (e.g., silver thickness about 0.3 micron). The inventors found that the reflectivity of the silver was reduced by up to 20% due to the silver becoming brownish. No significant long term degradation in reflectivity of the silver occurs when LEDs are driven by low currents (e.g., under 100 mA). If silver were plated directly over copper using an electroplate technique, there would also not be any significant reduction in reflectivity due to the thickness of the silver (typically over 3 microns). Previously, it was generally believed that the lowering of the overall brightness of LEDs after a long period was solely due to degradation of the LED and phosphor coating. The inventors have discovered that, for copper directly coated with a very thin layer of silver using an electroless process, such as an immersion silver process, there is a reduction in reflectivity after a long period of time at high currents that contributes to the overall reduction in LED brightness along with the reduction in brightness due to the degradation of the LED and phosphor.

What is needed is a technique for substantially maintaining the original reflectivity of a silver layer over copper pads for bonding to LED electrodes, even after thousands of hours of use, where the silver is a thin layer deposited by electroless deposition. What is also needed is a technique for preserving the 20% of LED light that is emitted from the sides of the LED or reflected by the encapsulation.

### SUMMARY

The inventors have discovered a technique to increase the light output and efficiency of solid state lighting (SSL) packages, such as LED packages. In one embodiment, a submount for an LED has relatively large copper pads formed on its top surface using an electroless process so that no electrical bias circuitry is required for the submount. The submount may be part of a submount wafer prior to dicing, and all the deposition steps described below are performed on a wafer scale.

The copper pads are then coated with nickel using an electroless process.

The nickel layer is then coated with silver using an electroless process, such as an immersion silver process. In one embodiment, the silver layer is less than one micron thick. If an immersion silver plating process is used, the silver layer is less than about 0.3 micron thick.

The inventors have found that the Ni layer prevents the reduction in reflectivity of the Ag after long periods of use (e.g., after 1000 hours under simulated environment conditions) while conducting the high current (300 mA to >1 amp) needed for high power LEDs. By not requiring a bias voltage for the plating, the pads can be isolated from other traces on the submount wafer so that no biasing traces need to be cut or etched away.

The Cu—Ni—Ag pads are much larger than typically metal pads used for LEDs since they are used both for bonding to the LED and for reflecting light emitted from edges of the LED and light that has been internally reflected by any encapsulating lens. The one or more reflective pads extend under the LED die, for direct bonding to a metal layer on the bottom of the die, and provide a relatively large reflecting surface substantially surrounding the LED. Preferably, the silver layer surrounds at least 75% of the periphery of the LED die and extends at least 1 mm around the periphery of the die to reflect the LED light.

If the LED dies are not flip-chips but instead include one or more electrodes on top for wire bonding, the bottom of the LED dies are still metalized for heat conduction and physical bonding to the submount, and the bottom metal is bonded to a large Cu—Ni—Ag pad for reflecting light, providing a bondable surface, and conducting heat through the submount.

The inventors estimate that about 20% of all light emitted by an LED die impinges on areas around the LED die by either a downward side emission or by total internal reflection (TIR) off the clear encapsulation (e.g., a hemispherical lens). The invention causes this 20% of light to be reflected upwards without the Ag layer losing its reflectivity after a long period.

In one embodiment, an array of LED dies are bonded to a single Cu—Ni—Ag pad, and the LEDs are connected in series. The pad is wide enough to reflect virtually all of the downward side light from the LED dies. The anode and cathode ends of the series string are connected to separate Cu—Ni—Ag pads for connection to a power supply.

The submount can be an aluminum core with a dielectric aluminum oxide layer, or the submount can be ceramic or other material.

In one embodiment, the submount has vias that lead to bottom pads for soldering or ultrasonic welding to corresponding pads on a circuit board. In another embodiment, the submount has top pads that are used for wire bonding to pads on a circuit board.

Various embodiments are described for flip-chip LEDs and wire bonded LEDs.

### BRIEF DESCRIPTION OF THE DRAWINGS

FIG. 1 is a cross-sectional view of a portion of a submount wafer being processed in accordance with one embodiment of the invention.

FIG. 2 is a cross-sectional view of the portion of the submount wafer of FIG. 1 being further processed in accordance with one embodiment of the invention.

FIG. 3A is a cross-sectional view of a completed portion of a submount wafer showing a light ray within the LED package being reflected upward by the relatively large reflecting electrodes on the top surface of the submount, where the LED is a flip-chip.

FIG. 3B is a top down view of FIG. 3A illustrating the oversized reflective contact pads.

FIG. 4 is a cross-sectional view of a completed portion of a submount wafer showing a light ray within the LED package being reflected upward by the relatively large reflecting electrodes on the top surface of the submount, where the LED has a wire bonded electrode.

FIG. 5 is a cross-sectional view of a portion of a submount wafer being processed in accordance with a second embodiment of the invention.

FIG. 6 is a cross-sectional view of the portion of the submount wafer of FIG. 5 being further processed in accordance with the second embodiment of the invention.

FIG. 7 is a cross-sectional view of the portion of a submount wafer of FIG. 6 being further processed in accordance with the second embodiment of the invention.

FIG. 8 is a cross-sectional view of a completed portion of a submount wafer in accordance with the second embodiment of the invention, showing a light ray within the LED package being reflected upward by the relatively large reflecting electrodes on the top surface of the submount, where the LED has a wire bonded electrode.

FIG. 9 is a cross-sectional view of a portion of a submount wafer being processed in accordance with a third embodiment of the invention.

FIG. 10 is a cross-sectional view of the portion of the submount wafer of FIG. 9 being further processed in accordance with the third embodiment of the invention.

FIG. 11 is a cross-sectional view of the portion of the submount wafer of FIG. 10 being further processed in accordance with the third embodiment of the invention.

FIG. 12 is a cross-sectional view of a completed portion of a submount wafer in accordance with the third embodiment of the invention showing a light ray within the LED package being reflected upward by a relative layer on the top surface of the submount, where the LED has a wire bonded electrode.

FIG. 13 is a top down view of a single submount having a relatively large Cu—Ni—Ag pad for bonding to the bottom metalized surfaces of an array of LED dies, where the Cu—Ni—Ag pad conducts heat and reflects LED light.

FIG. 14 is a cross-sectional view of the structure of FIG. 13 where the submount is insulating ceramic, and at least one copper via extends through the submount for a thermal path to a heat sink.

FIG. 15 is a cross-sectional view of the structure of FIG. 13 where the submount has an aluminum core with an aluminum oxide layer for electrical insulation.

Elements in the various figures that are the same or similar are labeled with the same element number.

### DETAILED DESCRIPTION

LED dies are extremely thin and brittle. Therefore, the LED manufacturer typically mounts the semiconductor LED die on a more robust submount and encapsulates the LED die. The fragile electrodes on the LED die are bonded, either directly or by gold wires, to a set of contact pads on the submount. The LED and wires (if any) are then typically encapsulated in a lens. The submount and LED die are then treated as a single unit thereafter. The submount has either top pads or bottom pads, not covered by the encapsulation, that are electrically connected by a metal layer to the LED electrodes, and the assembler mounts the submount to a larger circuit board by electrically bonding the exposed submount pads to metal pads on the circuit board.

The present invention relates to the submount rather than the circuit board.

The submounts described in the examples herein may have a ceramic core (so that its surfaces are insulating) or an aluminum core. For an aluminum core submount, a dielectric layer for supporting metal electrode pads is formed by selective oxidation of the aluminum surface by masking and anodizing. Other types of submounts can also be used.

Broadly, the various embodiments described herein form at least one relatively large reflective Cu—Ni—Ag pad for the LED die that extends well beyond the boundaries of the LED die. Any wire bonding pads are also Cu—Ni—Ag pads. The various metal layers are formed with electroless deposition processes, so the pads do not require any biasing traces connected to any biasing voltage. The Ag surface is easily soldered or welded to; the Cu layer has a very low resistivity so can conduct high currents without significant voltage drop; and the Ni barrier layer prevents tarnishing of the thin Ag layer (due to Cu—Ag migration) after long periods of use of the high power LED.

Using the invention, the Ag layer should substantially retain its 95+% reflectivity over the long life of the LED (e.g., over 50,000 hours).

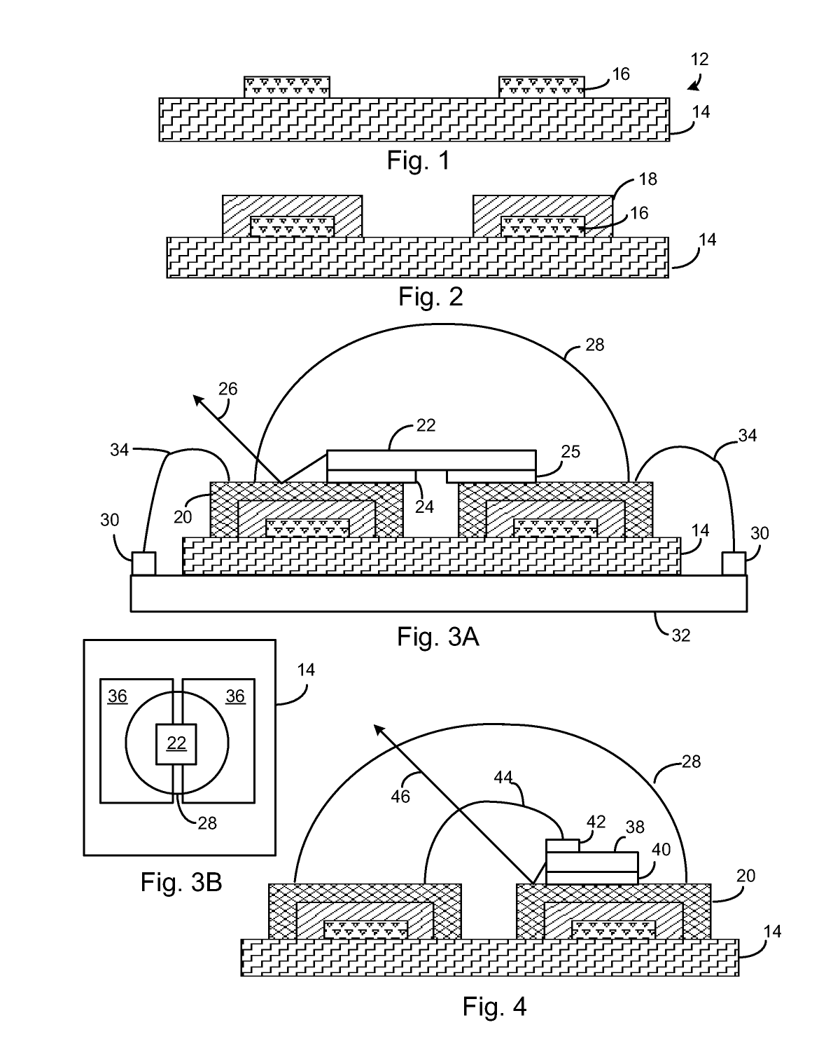

FIG. 1 is a portion of a submount wafer 12 that will later be diced. In the examples, the submount has an aluminum core, and all electrodes are formed over oxidized portions of the aluminum. The aluminum oxide portions are formed by masking (unless the entire surface is to be oxidized) and anodizing to form an insulating layer of any thickness.

In FIG. 1, it is assumed the aluminum oxide has been formed on the top surface of the submount core 14. The submount core 14 may also be ceramic or another electrically insulating material.

Copper pads 16 are then formed using an electroless process. Such processes include sputtering, evaporation, direct bonding to ceramic (DBC), printing, or other process that does not require electrical biasing. If required, the deposited copper layer may be patterned by masking and etching. The copper pads 16 may include electrodes for carrying current or thermal pads for only conducting heat. For thermal pads that will be electrically insulated from the LED die's electrodes, the thermal pads may be formed directly on the aluminum core so as not to conduct heat through the oxide layer, which has a thermal conductivity much lower than that of aluminum.

Since the copper pads 16 will later be covered with a silver layer for reflecting light and for solderability, the copper should be formed to substantially surround the area where the LED die(s) will be mounted so that the silver reflects almost all light emitted downward by sides of the LED die(s) and light reflected off the encapsulation by TIR.

As shown in FIG. 2, the copper pads 16 are coated with a nickel layer 18 by an electroless process. The width dimension of the electrodes is greatly compressed relative to the thickness dimension to illustrate the invention.

In one embodiment, the nickel layer 18 is deposited by electroless plating, which is a well known process. Plating typically provides a better bond than sputtering or printing. Electroless nickel plating is a chemical reduction process which depends upon the catalytic reduction process of nickel ions in an aqueous solution (containing a chemical reducing agent) and the subsequent deposition of nickel metal without the use of electrical energy. In the electroless nickel plating process, the driving force for the reduction of nickel metal ions and their deposition is supplied by a chemical reducing agent in solution. The reaction is accomplished when hydrogen is released by a reducing agent, normally sodium hypophosphite, and oxidized thus producing a negative charge on the surface of the part. This driving potential is essentially constant at all points of the surface of the component, provided the agitation is sufficient to ensure a uniform concentration of metal ions and reducing agents. Electroless nickel deposits are therefore very uniform in thickness.

Other possible deposition processes may include sputtering, evaporation, printing, or other known electroless processes.

As shown in FIG. 3A, a silver layer 20 is formed over the nickel layer 18 by an electroless process. In a preferred embodiment, the silver layer 20 is formed by an immersion silver process. The term immersion silver is a generic name for a variety of processes that utilize a reaction at the surface of the metal to be plated and, once that reaction is complete (i.e., the metal is covered by a thin layer of the plating metal), the process automatically stops to form a layer a fraction of a micron thick. One type of immersion silver process is described in U.S. Pat. No. 6,200,451, incorporated herein by reference, where copper traces and pads on a circuit board are coated with a silver layer for improved solderability. The Cu—Ag traces/pads in the '451 patent were not used to reflect light.

Other types of immersion silver deposition can be used and are well known, and the immersion silver process may be carried out by one of the many companies that perform such depositions using their own immersion silver process.

The silver layer 20 may be deposited using other processes such as sputtering, evaporation, printing, or other known electroless processes.

Also shown in FIG. 3A is a high power flip-chip LED 22 with bottom anode and cathode electrodes 24 and 25 directly bonded by solder or ultrasonic bonding to the silver layer 20. A high power LED is one that can be driven by greater than 300 mA. The silver layer 20 extends well beyond the edges of the LED 22 die, substantially surrounding the LED 22, to reflect almost all side light from the LED 22 that would normally be absorbed by the surface of the submount. One reflected light ray 26 is shown. In an actual embodiment, the Cu—Ni—Ag pads would extend further to the left and right of the LED 22 to provide room for the encapsulation and the bonding area for wire bonding the pads to a circuit board.

The LED 22 and a portion of the silver-coated metal pads are encapsulated by an epoxy or silicone lens 28. Exposed portions of the pads may be wire bonded to conventional metal pads 30 on a circuit board 32 by gold wires 34. Traces on the circuit board 32 electrically connect the anode and cathode electrodes 24 and 25 on the LED 22 to a power source. If the submount 14 were ceramic, copper vias may extend from the top surface of the submount to the bottom surface and terminate in bottom pads that are directly bonded to pads on the circuit board. The submount's bottom pads may be Cu—Ni—Ag pads formed at the same time as the top Cu—Ni—Ag pads.

FIG. 3B is an example of a possible top down view of the LED and submount of FIG. 3A, where the Cu—Ni—Ag pads 36 on the submount extend far beyond the edges of the LED 22 for reflecting the side light. The reflective pads 36 should be as close as practical to reflect the most light. The shape of the Cu—Ni—Ag pads 36 may be rectangular, circular, or other shapes depending on a desired reflection pattern. In one embodiment, the LED 22 is on the order of 1 mm² and the Cu—Ni—Ag pads 36 extend at least 1 mm around the LED 22. At least 75% of the LED 22 perimeter is surrounded by the silver layer 20. The bottom area of the LED 22 is referred to as a footprint. This same characteristic of the silver layer 20 surrounding at least 75% of the periphery of the LED 22 die applies to all embodiments.

FIG. 4 illustrates a non-flip chip LED 38 with a bottom electrode 40 and a top electrode 42. The bottom electrode 40 is soldered or welded to the silver layer 20 on a chip pad, and the top electrode 42 is wire bonded to the silver layer 20 on a wire bond pad via a gold wire 44. If the LED 38 had two top electrodes, the LED's bottom metallization would be a thermal pad soldered or welded to the chip pad as shown, and there would be two identical wire bond pads on opposite sides of the LED for the anode and cathode wire connections. A light ray 46 is shown being reflected by the silver layer 20 on the chip pad completely surrounding the LED 38 and extending at least 1 mm beyond the edges of the LED 38. The Cu—Ni—Ag pads may be formed in the ways described with respect to FIGS. 1-4.

If the submount body in FIGS. 1-4 were ceramic, a copper filled via may extend between the chip pad and the bottom surface of the submount for a thermal path between the LED 38 and a heat sink. The Cu—Ni—Ag electrodes may also be connected to bottom pads of the submount by copper filled vias for surface mounting of the submount on a circuit board.

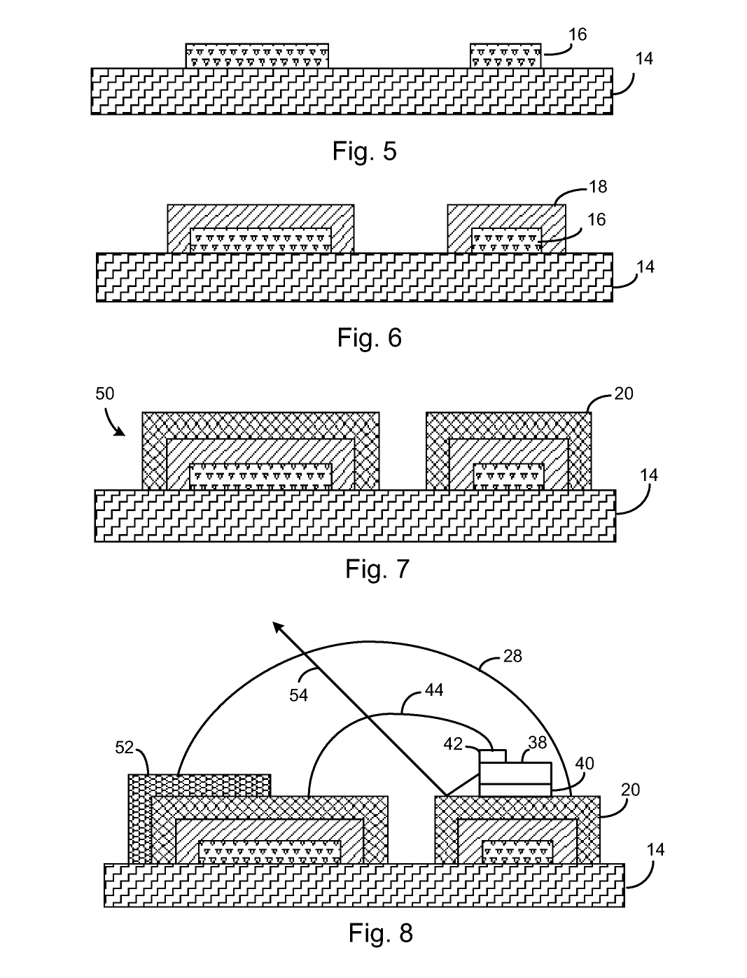

FIGS. 5-8 illustrate the fabrication of another embodiment submount for a high power LED. FIGS. 5-7 are identical to FIGS. 1-3 except that the left Cu—Ni—Ag pad 50 (FIG. 7) is wider. In FIG. 8, an additional reflective layer 52 of aluminum or silver is deposited, such as by spraying, over the silver layer 20 for increased reflectivity. The reflective layer 52 is not used for bonding so it can be any suitable material. A light ray 54 is shown being reflected off the Cu—Ni—Ag chip pad. In one embodiment, there is another reflective pad to the right of the LED 38 that may or may not be used as an electrode. The additional pad is used for reflecting light that has been reflected off the lens 28 by TIR.

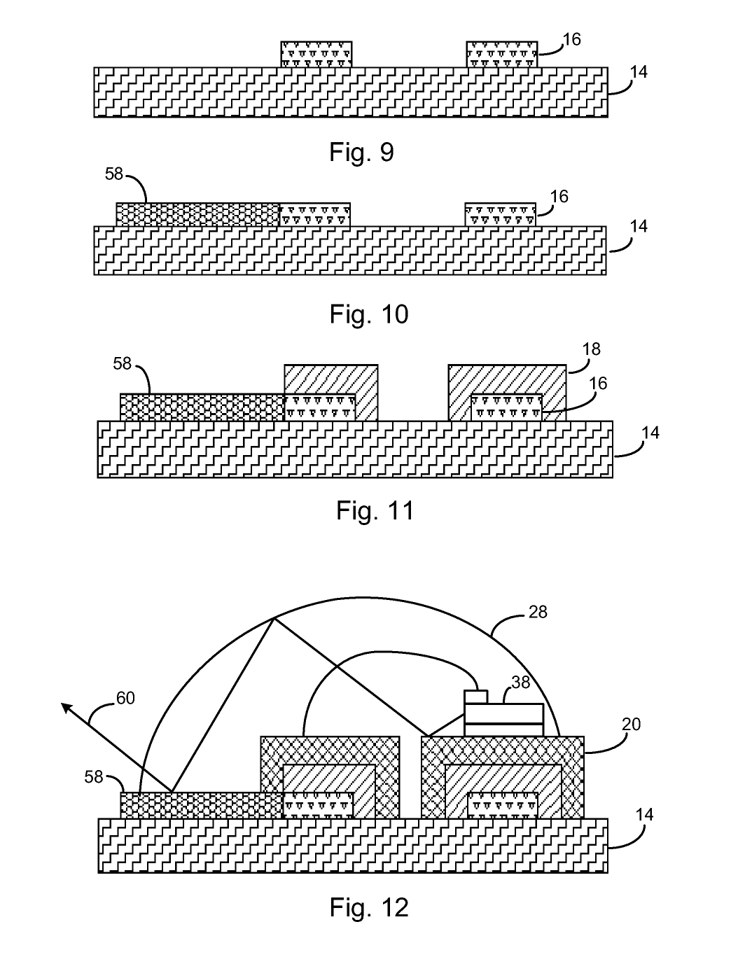

FIGS. 9-12 illustrate another embodiment of the invention, where a reflective layer 58 is deposited, such as by spraying, directly on the submount 14 surface. The reflective layer 58 will not carry current or be soldered to so it can be any suitable material, such as aluminum or silver. The Cu—Ni—Ag pads may be similar to those in the previous figures. The reflective layer 58 is primarily used to reflect light reflected by the lens 28 by TIR, as shown by the light ray 60.

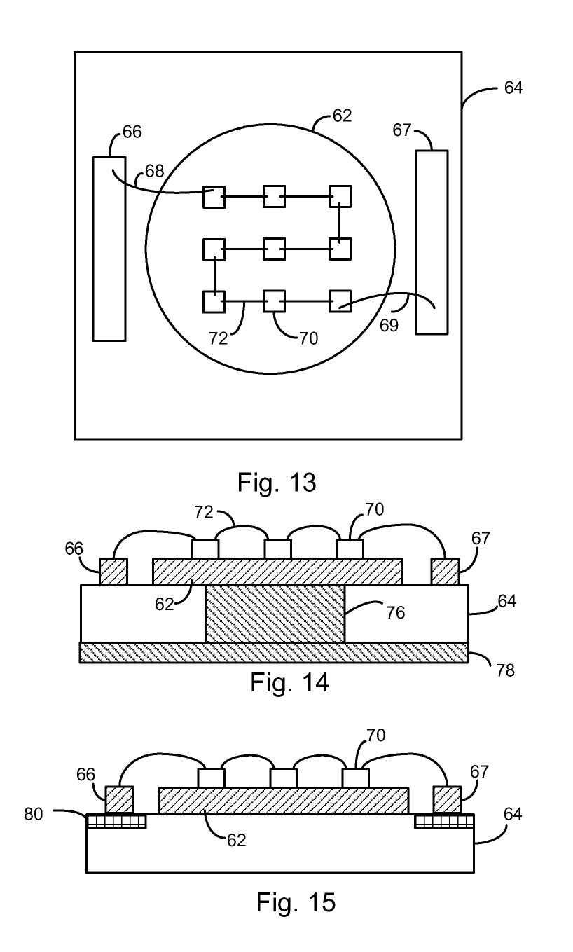

FIGS. 13-15 illustrate a single Cu—Ni—Ag pad 62 supporting an array of LED dies. FIG. 13 is a top down view of a submount 64 that may be an aluminum core, a ceramic, or other type of material. The submount may be rectangular, hexagonal, or any other suitable shape. Cu—Ni—Ag electrode pads 66 and 67 for the anode and cathode are connected by gold wires 68 and 69 to the anode and cathode ends of a serial string of LED dies 70, interconnected by gold wires 72. The bottom of each die 70 is metalized and soldered or welded to a large central Cu—Ni—Ag pad 62 that serves as a reflector and heat conductor. If the submount has an aluminum core, the pads 66 and 67 are electrically insulated from the aluminum by an aluminum oxide layer.

If the LED dies 70 were flip-chips, the Cu—Ni—Ag pattern would be such that the various bottom LED electrodes were connected in series.

All the LED dies 70 may be connected in parallel or a combination of series and parallel. There may be a 5×5 array of LEDs powered by a high driving voltage.

FIG. 14 is a cross-sectional view of FIG. 13 if the submount 64 is ceramic. One or more openings (vias) in the submount are filled with copper 76 to conduct heat to a bottom copper pad 78, which is thermally coupled to a heat sink (not shown). The submount may have peripheral bolt holes for bolting the submount to a metal heat sink. A thermal grease or other squishable thermal conductor is dispensed between the submount and heat sink to ensure full thermal contact over the entire back surface of the submount.

FIG. 15 is a cross-sectional view of FIG. 13 if the submount 64 is an aluminum core type. At least the anode and cathode pads 66 and 67 are insulated from the aluminum by an aluminum oxide layer 80. The central Cu—Ni—Ag pad 62 may be formed directly on the aluminum or on the aluminum oxide 80. For improved thermal conductivity to the bottom surface of the submount, the pad 62 would be formed directly on the aluminum. It is optional whether to provide a copper layer on the bottom surface of the submount since the copper layer is useful for soldering or diffusion bonding the bottom surface to a heat sink. If the substrate is to be bolted to a metal heat sink, a bottom copper layer is not necessary.

Although it is preferred that the silver layer 20 in the various embodiments be formed using the immersion silver process (forming a very thin layer of silver), any suitable electroless deposition process may be used to deposit the silver layer, such as sputtering, printing, dispensing, etc.

Although silver has been used in the preferred embodiment, there may be other suitable metals that are solderable/weldable and also sufficiently reflective. Such materials may be deposited by electroless plating, sputtering, printing, dispensing, etc. over the copper. Depending on the non-silver material, the Ni layer may be eliminated.

Further, since only a small area over the copper needs to be solderable or weldable, all other areas of the copper may be covered with a highly reflective non-metal, while the attachment area only needs to be gold or silver.

The metals described herein may be alloys as well as the pure elemental metals, and the pure elemental metal has been used to also represent such alloys when the elemental metal is a majority of the alloy.

Having described the invention in detail, those skilled in the art will appreciate that given the present disclosure, modifications may be made to the invention without departing from the spirit and inventive concepts described herein. Therefore, it is not intended that the scope of the invention be limited to the specific embodiments illustrated and described.

What is claimed is:

1. A method comprising:
providing a submount body configured for having mounted thereon a solid state lighting (SSL) device having a footprint;
patterning a copper layer over the submount;
coating the copper layer with nickel using an electroless deposition process without electrically biasing the copper layer with an external power source; and
coating the nickel layer with silver to form a silver layer, creating at least a Cu—Ni—Ag mounting pad, the silver layer being formed using an electroless deposition process, the silver layer being less than one micron thick,
wherein the silver layer extends under the footprint of the SSL device and surrounds at least 75% of a periphery of the footprint to reflect light emitted by the SSL device, the silver layer providing a solderable or weldable surface for mounting of the SSL device onto the Cu—Ni—Ag mounting pad.

2. The method of claim 1 wherein the copper layer is also patterned to form at least one electrode for carrying current, wherein at least part of the at least one electrode is a Cu—Ni—Ag electrode pad formed concurrently with the formation of the Cu—Ni—Ag mounting pad.

3. The method of claim 1 wherein the silver layer is formed by an immersion silver process.

4. The method of claim 1 wherein the silver layer is less than about 0.3 micron thick.

5. The method of claim 1 wherein the silver layer extends beyond at least 75% of the periphery of the footprint by at least 1 mm.

6. The method of claim 1 further comprising mounting the SSL device on the Cu—Ni—Ag mounting pad by soldering or welding.

7. The method of claim 1 wherein the Cu—Ni—Ag mounting pad is a thermal pad for conducting heat from the SSL device to a heat sink.

8. The method of claim 1 wherein the SSL device is a flip-chip having a bottom anode electrode and a bottom cathode electrode, wherein the Cu—Ni—Ag mounting pad is an anode electrode, the method further comprising forming a Cu—Ni—Ag cathode electrode pad concurrently with forming the Cu—Ni—Ag mounting pad, wherein the SSL device's anode electrode is bonded to the Cu—Ni—Ag mounting pad, and the SSL device's cathode electrode is bonded to the Cu—Ni—Ag cathode electrode.

9. The method of claim 1 wherein the Cu—Ni—Ag mounting pad is a thermal pad for conducting heat from the SSL device to a heat sink, wherein the SSL device has at least one top electrode, the method further comprising forming at least one Cu—Ni—Ag electrode pad concurrently with the formation of the Cu—Ni—Ag mounting pad, and bonding a wire between the top electrode and the Cu—Ni—Ag electrode pad.

10. The method of claim 1 wherein the SSL device is a light emitting diode.

11. The method of claim 1 further comprising depositing a reflective material over the submount body and in contact with the silver layer, wherein the reflective material does not carry current to the SSL.

12. The method of claim 1 further comprising encapsulating the SSL and at least part of the Cu—Ni—Ag mounting pad.

13. The method of claim 12 further comprising forming additional Cu—Ni—Ag regions on the submount that are at least partially encapsulated, the additional Cu—Ni—Ag regions reflecting light internally reflected by a boundary of encapsulation material.

14. The method of claim 1 further comprising forming one or more Cu—Ni—Ag contact pads on the submount for electrical connection to a circuit board on which the submount is to be mounted, the Cu—Ni—Ag contact pads being formed at the same time that the Cu—Ni—Ag mounting pad is formed.

15. The method of claim 1 further comprising mounting a plurality of SSL devices on the Cu—Ni—Ag mounting pad.

16. The method of claim 15 further comprising connecting at least some of the SSL devices in series.

17. The method of claim 1 further comprising bonding at least a bottom metal layer of the SSL device to the Cu—Ni—Ag mounting pad.

18. A structure comprising:
a submount body configured for having mounted thereon a solid state lighting (SSL) device, the SSL device having a footprint;
a copper layer patterned over the submount;
the copper layer being coated with nickel using an electroless deposition process without electrically biasing the copper layer with an external power source; and
the nickel layer being coated with silver to form a silver layer, creating at least a Cu—Ni—Ag mounting pad, the silver layer being formed using an electroless deposition process, the silver layer being less than one micron thick,
wherein the silver layer extends under the footprint of the SSL device and surrounds at least 75% of a periphery of the footprint to reflect light emitted by the SSL device, the silver layer providing a solderable or weldable surface for mounting of the SSL device onto the Cu—Ni—Ag mounting pad

19. The structure of claim 18 further comprising at least a bottom metal layer of the SSL device bonded to the Cu—Ni—Ag mounting pad.

20. The structure of claim 18 wherein the copper layer is also patterned to form at least one electrode for carrying current, wherein at least part of the at least one electrode is a Cu—Ni—Ag electrode pad formed concurrently with the formation of the Cu—Ni—Ag mounting pad.

21. The structure of claim 18 wherein the silver layer is less than about 0.3 micron thick.

22. The structure of claim 18 wherein the silver layer extends beyond at least 75% of the periphery of the footprint by at least 1 mm.

23. The structure of claim 18 wherein the Cu—Ni—Ag mounting pad is a thermal pad for conducting heat from the SSL device to a heat sink.

24. The structure of claim 18 wherein SSL device is a flip-chip having a bottom anode electrode and a bottom cathode electrode, wherein the Cu—Ni—Ag mounting pad is an anode electrode, the structure further comprising a Cu—Ni—Ag cathode electrode pad, wherein the SSL device's anode electrode is bonded to the Cu—Ni—Ag mounting pad, and the SSL device's cathode electrode is bonded to the Cu—Ni—Ag cathode electrode.

25. The structure of claim 18 wherein the Cu—Ni—Ag mounting pad is a thermal pad for conducting heat from the SSL device to a heat sink, wherein the SSL device has at least one top electrode, the structure further comprising at least one Cu—Ni—Ag electrode pad, and a wire bonded to the top electrode and the Cu—Ni—Ag electrode pad.

26. The structure of claim 18 wherein the SSL is a light emitting diode.

27. The structure of claim 18 further comprising additional Cu—Ni—Ag regions on the submount that are at least partially encapsulated along with the SSL device and Cu—Ni—Ag mounting pad, the additional Cu—Ni—Ag regions reflecting light internally reflected by a boundary of encapsulation material.

28. The structure of claim 18 further comprising a plurality of SSL devices mounted on the Cu—Ni—Ag mounting pad, wherein at least some of the SSL devices are connected in series.
